(19) United States
(12) Patent Application Publication
(10) Pub. No.: US 2006/0059394 A1
(43) Pub. Date: Mar. 16, 2006

(54) Loop-back method for measuring the interface timing of semiconductor memory devices using the normal mode memory

(76) Inventor: Wolfgang Spirkl, Germering (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/220,169

(22) Filed: Sep. 6, 2005

(30) Foreign Application Priority Data
Sep. 6, 2004 (DE) DE 102004043051.9

(51) Int. Cl. G11C 29/00

(52) U.S. Cl. 714/718

(57) ABSTRACT

The invention relates to a method for testing a semiconductor memory device, the semiconductor memory device being able to be operated in a normal operating mode and a test mode. The method for testing includes communicating test input data to be used for a test to the semiconductor memory device; storing the test input data in memory cells of a memory area of the semiconductor memory device; and reading out the stored test input data from the memory cells for carrying out a test in order to obtain test output data, the memory area in which the test input data are stored in the test mode being used for storing data in the normal operating mode. In addition, the invention relates to a semiconductor memory device and a system for testing a semiconductor memory device.

### CROSS-REFERENCE TO RELATED APPLICATIONS

This application claims foreign priority benefits under 35 U.S.C. §119 to co-pending German patent application number DE 10 2004 043051.9, filed 6 Sep. 2004. This related patent application is herein incorporated by reference in its entirety.

### BACKGROUND OF THE INVENTION

1. Field of the Invention

The present invention relates to a method and a system for testing a semiconductor memory device, and to a semiconductor memory device.

2. Description of the Related Art

Methods for testing semiconductor memory devices, in particular, methods for testing the interface timing, are known such that a test pattern is communicated to and stored in the semiconductor memory device. In this case, a particular memory area is provided for storing the test pattern. In addition, a multiplexer is provided in the semiconductor memory device, which makes it possible to change over between the memory area used in a normal operating mode and the special memory area used for the test.

The arrangement described above has its disadvantages. Under the above method, it is necessary to allocate additional memory area and use a multiplexer in connection with the semiconductor memory device.

Consequently, there is a need to provide a method and a system for testing a semiconductor memory device and a semiconductor memory device capable of simple and cost-effective testing, in particular testing of the interface timing of the semiconductor memory device.

### SUMMARY OF THE INVENTION

The invention provides a method for testing a semiconductor memory device, capable of operating in a normal mode and a test mode. The method includes communicating test input data to be used for a test to the semiconductor memory device, in particular from an external test unit; storing the test input data in memory cells of a memory area of the semiconductor memory device; and reading out the stored test input data from the memory cells for carrying out a test in order to obtain test output data, in particular for testing the propagation time delays in the semiconductor memory device, the memory area in which the test input data are stored in the test mode being used for storing data in the normal operating mode.

The use of a memory area, which is used for storing data in the normal operating mode and for storing test input data in the test mode, will result in a reduction of the required area of the semiconductor memory device, since there is no need for an additional memory area for storing the test input data. Furthermore, it is not necessary to provide a multiplexer that enables a changeover between the memory area used in the test mode and the memory area used in the normal operating mode. In addition, the use of the memory area which is used for storing data in the normal operating mode for storing the test input data makes it possible to store a larger number of test patterns or test patterns having a larger number of bits. In particular, the size of the test pattern can only be limited by the size of the allocated memory area.

Furthermore, in the present invention, the test can be carried out under more realistic conditions compared with methods taught by the prior art, since noise that occurs during the use of the memory cell array is also present during test operation.

Preferably, the stored test input data are read out from the memory cells at least partially in parallel and the read-out step comprises a step of converting the test input data read out from the memory cell array in parallel into serial data, which are used for carrying out the test, in particular with the aid of a parallel-to-serial conversion device.

Preferably, provision is made of a predeterminable number of parallel lines between the memory cell array and the parallel-to-serial conversion device, via which the test input data are read out in parallel.

Preferably, the method comprises a step of comparing the test output data with the read-out test input data in a comparison device.

Preferably, serial test input data are compared with serial test output data.

In this case, the test output data are converted into a format which enables the converted test output data to be compared with the test input data stored in the memory area. In particular, in this case, the test input data are compared bit by bit respectively with the corresponding bits of the test output data.

Preferably, the method comprises a step of registering or cumulating the comparison results or an item of error information in an error register for generating a comparison test result.

In particular, this method involves registering whether errors have occurred during the comparison step. The errors that have occurred are registered in the error register and a comparison test result, i.e., a test result reflecting the output of the comparison between test input data and test output data, is generated in accordance with the content of the error register.

Furthermore, the method may comprise a step of outputting a test result to the external test unit.

In addition, the method comprises a step of storing the test output data and/or a test result in the same and/or a further memory area, which is used for storing data in the normal operating mode.

In particular, it is not necessary in this case for the test input data and the test output data to be compared with one another in the semiconductor memory device when the device is under test. Furthermore, It is not necessary to provide the test input data at a precise point in time in order to enable a comparison with the test output data.

It may be provided that the test output data stored in this way, after the conclusion of the test, are read out by the external test device and are evaluated there.

Preferably, the test output data include serial data and the method includes a step of at least partially converting the serial test output data into parallel data, which, in particular, are to be written to the memory cell array, preferably with the aid of a serial-to-parallel conversion device.

The method may include a step of comparing a converted test output data with the stored test input data in a comparison device.

Particularly if a parallel-to-serial conversion has taken place during the read-out of the test output data, it is advantageous to carry out a serial-to-parallel conversion for the test output data. The parallel test output data are preferably compared with the parallel test input data.

The method furthermore preferably includes a step of creating a data test result from or using the test output data.

A data test result in the sense of the invention is understood to mean in particular a test result which is generated essentially only using the test output data themselves. Consequently, it is not necessary to carry out a comparison of test input data and test output data in which the test input data have to be kept ready with a very precise timing in order to be able to be compared with the test output data.

Preferably, the step of creating the data test result includes a step of creating or calculating a signature from the test output data.

The data test result can thus be obtained in the form of a signature that is calculated or created from the test output data. In this case, a signature is understood to mean an unambiguous function of the test output data in the case of which the probability of the signature being correct even though the data are false, or the significance level or the so-called “false pass probability”, is sufficiently low.

It is further preferred for the test output data, for creating the signature, to be combined at least partially in groups.

It may be provided that test output data are present at different locations on the semiconductor device. In order to achieve a circuit construction that is as simple as possible, and thus not to enlarge the size of the semiconductor device unnecessarily, test output data which are present in each case in a locally delimited or adjacent region can be grouped, and a signature can subsequently be created from these grouped data.

A step of comparing the created signature with a desired signature may be further provided.

In this case, the desired signature is a signature that has been calculated in the front-end stages. The desired signature may be determined in particular by using a known semiconductor memory device (so-called “known good device”), preferably under conditions which permit a relaxed timing. As an alternative, the desired signature may be determined computationally. Consequently, this desired signature may be determined either experimentally or by simulation.

The comparison step may be effected in or on the semiconductor memory device and/or in an external test device.

A signature register is preferably used for creating the signature.

The signature register is preferably an MISR, i.e., a multiple input signature register.

Preferably, the test input data contain or comprise redundant information, and the step of creating the data test result is effected using the redundant information of the test output data.

Consequently, it is possible to use a redundancy method in order to create the data test result.

It is further preferred for parity bits which contain an item of information about a predetermined number of further test input data bits to be provided in the test input data.

The provision of the parity bits thus makes it possible to obtain an item of information about whether or not an error occurred during the test.

The semiconductor memory device to be tested may include output drivers in particular for amplifying a data signal to be read out from the semiconductor memory device, input drivers in particular for amplifying a data signal to be written to the semiconductor memory device and data pads and the method may furthermore include a step of passing or conducting the read-out test data via an output driver, at least one data pad and an input driver, the input drivers and output drivers being switched or designed during the test in such a way as to enable data to be simultaneously read from and written to the semiconductor memory device.

Consequently, it is possible to measure, in particular, the propagation times in the input/output circuits of the semiconductor memory device.

Preferably, the output driver and the input driver via which the test data are conducted are assigned in each case to the same data pad.

A so-called “inner loop” is thus formed, the test signals essentially being communicated only within the semiconductor memory device to be tested.

It may be provided that essentially each data pad is signal-connected to a data contact and, in the test mode: in each case two data contacts are signal-connected to one another, in particular via an external load resistor; and the test data are conducted via an output driver of a first data pad, the first data pad, a first data contact signal-connected to the first data pad, the second data contact signal-connected to the first data contact, the second data pad signal-connected to the second data contact, and the input driver of the second data pad.

A so-called “external loop” is thus formed. In this case, the test signals are conducted out of the semiconductor memory device via a first data contact or ball and conducted in via a second data contact or ball, which is signal-connected to the first data contact.

The read-out order of the test data stored in the memory cells is preferably altered in order to generate different test patterns.

In particular, for this purpose it is possible to use the counting device used in the normal operating mode for an auto-refresh or self-refresh. Different test patterns can be generated depending on the order in which the test data stored in the memory cells are read out.

The invention furthermore provides a semiconductor memory device which can be operated in a normal operating mode and a test mode, the semiconductor memory device includes: at least one memory cell array which is used for storing data in the normal operating mode; the semiconductor memory device being designed in such a way that, in the test mode, test input data can be stored in the memory cell array; and the stored test input data, for carrying out a test in order to obtain test output data, can be read out from the memory cell array.

Preferably, the semiconductor memory device includes a parallel-to-serial conversion device for converting test input data read out from the memory cell array in parallel into serial data which are used for carrying out the test.

Furthermore, the semiconductor memory device may include a comparison device for comparing the test output data with the read-out test input data in order to obtain error information.

Preferably, the semiconductor memory device includes an error register for registering or cumulating the error information and generating a comparison test result.

It is further preferred for the semiconductor memory device to include an output device for outputting a test result to the external test unit.

The semiconductor memory device is preferably designed for storing the test output data and/or a test result in the same and/or a further memory area, which is used for storing data in the normal operating mode.

Furthermore, the semiconductor memory device may include a serial-to-parallel conversion device for converting serial test output data into parallel data, which, in particular, are to be written to the memory cell array.

Preferably, the comparison device is designed for comparing the converted test output data with the stored test input data in order to obtain error information.

Preferably, the semiconductor memory device includes a data test result creating device for creating a data test result from the test output data.

It is further preferred for the data test result creating device to include a signature device for creating or calculating a signature from the test output data.

The semiconductor memory device preferably comprises a signature comparison device for comparing the created signature with a desired signature.

Consequently, the comparison step may be effected in or on the semiconductor memory device.

As an alternative, the comparison step may be effected in an external test device.

The semiconductor memory device may include a signature register, in particular a multiple input signature register (MISR), for creating the signature.

Preferably, the test input data contain or include redundant information and the semiconductor memory device comprises a device for creating the data test result using the redundant information of the test output data.

Parity bits containing an item of information about a predetermined number of further test input data bits are preferably provided in the test input data.

The semiconductor memory device preferably includes output drivers in particular for amplifying a data signal to be read out from the semiconductor memory device, input drivers in particular for amplifying a data signal to be written to the semiconductor memory device and data pads and is designed in such a way that in the test mode an output driver, at least one data pad and an input driver are signal-connected to one another and the input drivers and output drivers are switched or designed during the test in such a way as to enable data to be simultaneously read from and written to the semiconductor memory device.

Preferably, the output driver and the input driver via which the test data are conducted are assigned in each case to the same data pad.

It may be provided that essentially each data pad is signal-connected to a data contact and, in the test mode: in each case two data contacts are signal-connected to one another via an external load resistor; and the semiconductor memory device is designed in such a way that the test data are conducted via an output driver of a first data pad, the first data pad, a first data contact signal-connected to the first data pad, the second data contact signal-connected to the first data contact, the second data pad signal-connected to the second data contact, and the input driver of the second data pad.

The invention furthermore provides a system for testing a semiconductor memory device, including: a semiconductor memory device in accordance with the present invention or a preferred embodiment thereof; an external test unit for driving the semiconductor memory device; the external test unit being designed to bring the semiconductor memory device into the test mode for a test operation.

### BRIEF DESCRIPTION OF THE DRAWINGS

So that the manner in which the above recited features, advantages and objects of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic view of a semiconductor memory device in accordance with a first preferred embodiment of the present invention;

FIG. 2 shows a schematic view of a semiconductor memory device in accordance with a second preferred embodiment of the present invention; and

FIG. 3 shows a schematic view of a semiconductor memory device in accordance with a third preferred embodiment of the present invention.

### DETAILED DESCRIPTION OF THE PREFERRED EMBODIMENT

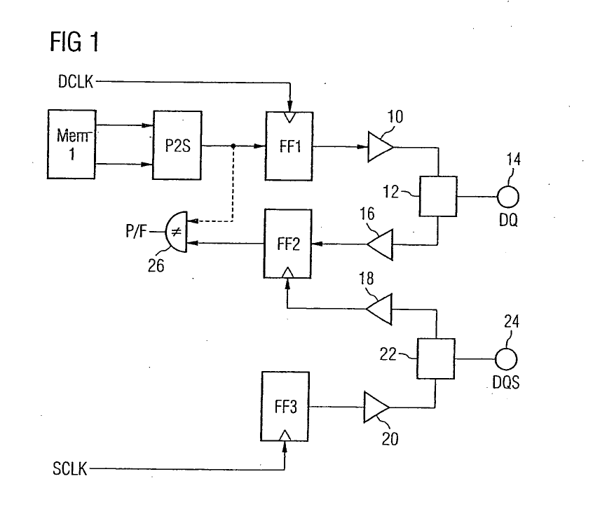

First, a description is given below of a semiconductor memory device in accordance with a first preferred embodiment of the present invention with reference to FIG. 1.

FIG. 1 shows a schematic view of a semiconductor memory device in accordance with a first preferred embodiment of the present invention. The semiconductor memory device shown in FIG. 1 can be operated in a normal operating mode and a test mode.

The semiconductor memory device shown includes a memory area Mem 1 having a multiplicity of memory cells arranged in matrix-like fashion. The memory area Mem 1 is signal-connected to a parallel-to-serial conversion device P2S via a plurality of connecting lines.

In the parallel-to-serial conversion device P2S, data read out from the memory area Mem 1 in parallel are converted into serial data. The serial output of the parallel-to-serial conversion device P2S is signal-connected to the data input of a first flip-flop FF1. A clock signal DCLK is present at the clock input of the first flip-flop FF1. The clock signal is used for a read-out of the data stored in the memory area Mem 1, and the data present at the data input of the first flip-flop FF1 is accepted with the edge of the clock signal.

Furthermore, an output driver 10 for the data signal DQ is signal-connected to the signal output of the first flip-flop FF1. The output driver 10 is signal-connected to a data pad 12. The data pad 12 is signal-connected to a data contact or ball 14, through which the semiconductor memory device can be connected to an external circuit. Data signals DQ are transmitted via the data contact 14. Furthermore, the data pad 12 is signal-connected to an input driver 16. The input driver 16 is signal-connected to the data input of the second flip-flop FF2.

Furthermore, an input driver 18 for a data clock signal DQS and an output driver 20 for a clock signal are provided. The input driver 18 and the output driver 20 are signal-connected to a data clock pad 22 and data clock pad 22 is signal-connected to a data clock contact or ball 24. The output of the input driver 18 is signal-connected to the clock input of the second flip-flop FF2. The output of the second flip-flop FF2 is signal-connected in the test mode to a comparison device 26. Furthermore, the output of the parallel-to-serial conversion device P2S is likewise signal-connected in the test mode to an input of the comparison device 26 (this is illustrated in a dashed manner in FIG. 1).

In the connection between the parallel-to-serial conversion device P2S and the comparison device 26, it is possible to provide a delay device (not illustrated) for delaying the signal transmitted via this connection.

A third flip-flop FF3 is provided, and a clock signal SCLK for a data clock signal is provided at the clock input of the third flip-flop FF3. The signal output of the third flip-flop FF3 is signal-connected to the input of the output driver 20. Consequently, with each clock of the clock signal SCLK, a clock is output to the data clock pad 22 via the output driver 20.

A test result signal P/F, specifying whether or not the required test conditions were met, is output at the output of the comparison device 26.

The semiconductor memory device has a multiplicity of the configurations described above. However, only one path for data signals DQ and one path for data clock signals DQS are specified here for the sake of simplicity.

First, the operation of the semiconductor memory device in the normal operating mode is described below.

If data are intended to be read out from the semiconductor memory device, the output driver 10 is switched such that it enables a signal transmission, and the input driver 16 is switched such that it does not enable a signal transmission. The data stored in the memory area Mem 1 are first read out in parallel and converted into serial data by the parallel-to-serial conversion device P2S. By way of the first flip-flop F1, with each clock of the clock signal DCLK, the data bits are provided at the output of the first flip-flop FF1 and are output via the output driver 10, to the data pad 12 and to the data contact 14.

If, by contrast, data are intended to be written to the semiconductor memory device, the output driver 10 is switched such that a signal transmission is not possible, and the input driver 16 is switched such that a signal transmission is enabled. Furthermore, the signal output of the second flip-flop FF2 is signal-connected to a memory area or a serial-to-parallel conversion device connected upstream. The data transmitted to the semiconductor memory device are written to the memory area with each clock of a data clock signal DQS that has been transmitted via the data clock contact 24.

The operation of the semiconductor device in the test mode is described below. For this purpose, an external test device (not shown) transmits a signal to the semiconductor memory device in order for the semiconductor memory device to be operated in the test mode. A test pattern or test data is transmitted to the semiconductor memory device by the external test device. The test input data are stored in the memory area Mem 1, which is the memory area used for storing data in the normal operating mode. During test operation, the output drivers 10 and 20 and input drivers 16 and 18 are switched such that a signal transmission is made possible. In the configuration illustrated in FIG. 1, a so-called “internal loop” arrangement is thus made possible, wherein test signals read out from a memory area are transmitted via the output driver 10, the data pad 12 and the input driver 16 into the semiconductor memory device again.

The detailed sequence is described below.

The test input data that have been read out from the memory area Mem 1 and converted in the parallel-to-serial conversion device P2S are latched in the first flip-flop FF1 with the clock signal DCLK, or accepted with the rising or falling edge of the clock signal DCLK, and transmitted via the output driver 10, the data pad 12 and the input driver 16. The test data thus transmitted are latched in the second flip-flop FF2 with a clock signal which is produced from the output signal of the third flip-flop FF3, which has been generated with the aid of the clock signal SCLK and has been transmitted via the output driver 20, the data clock pad 22 and the input driver 18. The output signal present at the second flip-flop FF2 is, then fed to the comparison device 26. In the comparison device 26, the test output signal obtained is compared with the corresponding test input signal present at the output of the parallel-to-serial conversion device P2S. The test input signal is correspondingly delayed (not illustrated) in this case in order to enable the two signals to be compared.

In the comparison device 26, the nonmatching data bits of the two test signals are registered and cumulated and a test result signal P/F is output. The test result signal specifies whether or not a maximum number of errors has been exceeded. The signal P/F may be output to the external test device, for example. The signal that is output is, a comparison test result obtained by comparing the test input data with the test output data.

With the aid of the arrangement described above, it is possible to test the propagation time delay of signals in the semiconductor memory device. Because the test input signals are stored in a memory area which is used for storing data in the normal operating mode, it is not necessary to provide further memory areas dedicated solely for test operation. Furthermore, in comparison with the prior art, it is not necessary to provide multiplexers in order to switch back and forth between the different memory areas.

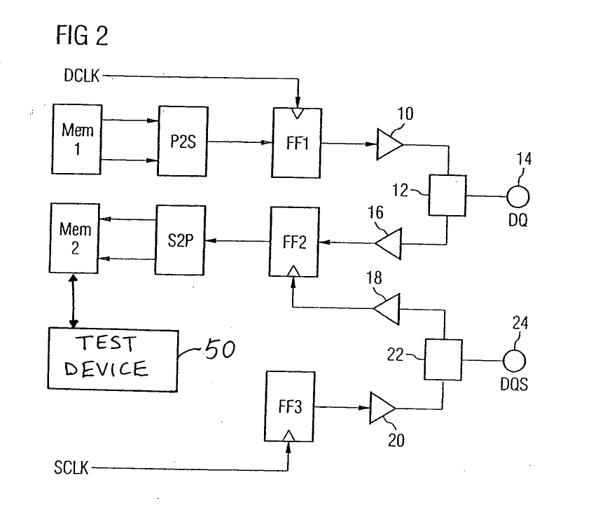

A second preferred embodiment of the present invention is described below with reference to FIG. 2. FIG. 2 shows a schematic view of a semiconductor memory device in accordance with a second preferred embodiment of the present invention.

FIG. 2 shows a similar view to FIG. 1. Elements of the semiconductor memory device which are the same as in the first embodiment are designated by the same reference symbols, and a detailed description thereof is dispensed with.

The semiconductor memory device in accordance with the second embodiment generally has the same structure as the semiconductor memory device in accordance with the first embodiment, the difference being that the comparison device 26 is not provided. In the semiconductor memory device shown, the output of the second flip-flop FF2 is signal-connected to a second memory area Mem 2 via a serial-to-parallel conversion device S2P.

The functioning of the semiconductor memory device during normal operation is the same as that of the semiconductor memory device in accordance with the first embodiment.

In test operation, the output signal of the second flip-flop FF2 is not compared with the test input data, as in the first embodiment. Rather, the test output data are converted into parallel data by means of the serial-to-parallel conversion device S2P and stored in the second memory area Mem 2. After the conclusion of the test, the stored test output data can be read out (e.g., performing read-out operations as in normal operation from the second memory area Mem 2) and evaluated utilizing a test device 50 which may be incorporated in the memory device or an external test device.

Consequently, in this embodiment, it is not necessary for the test input data to be kept ready again at a suitable point in time in order for it to be compared with the test output data.

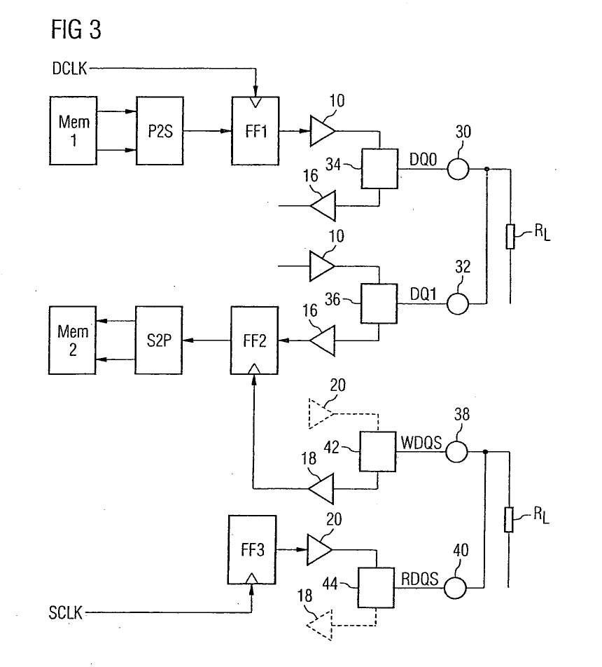

A third preferred embodiment of the present invention will now be described with reference to FIG. 3. FIG. 3 is a schematic view of a semiconductor memory device in accordance with a third embodiment.

The embodiment shown in FIG. 3 corresponds to that embodiment shown in FIG. 2 with the difference that an external loop is formed in the test mode. In this case, a first data contact 30 is signal-connected to a second data contact 32 via an external load resistor R_{L}. The first data contact 30 is signal-connected to a first data pad 34, and the second data contact 32 is signal-connected to a second data pad 36. In a similar manner, two data clock contacts 38 and 40 are signal-connected to one another via an external load resistor R_{L} during the test mode.

In the test mode, an external loop is formed by the output driver 10, which is signal-connected to the first data pad 34, the first data contact 30, the second data contact 32, the second data pad 36 and the input driver 16, which is signal-connected to the second data pad 36. In this case, the output drivers 10 and input drivers 16 are in each case switched such that the output driver 10 associated with a first data contact enables a signal transmission, and the input driver 16 of the associated data contact 32 in the pair-wise arrangement of two data contacts enables a signal transmission. The respective other output drivers 10 and input drivers 16 are switched such that signal transmission is not made possible. A similar arrangement is produced for the data clock signals DQS. The operation of the semiconductor memory device in the test mode is the same as that in accordance with the second embodiment, and a detailed description thereof is dispensed with.

Further embodiments that are not illustrated are described below.

It may further be provided that the comparison device 26 shown in FIG. 1 can be combined with an external loop arrangement as shown in FIG. 3.

It may further be provided that the parallel test output data are compared with test input data stored in the memory area Mem 1.

Furthermore, a data test result may be formed from the test output data that are output at the second flip-flop FF2, where a data test result is obtained using only the test output data without comparison to the test input data. This has the advantage that it is not necessary to keep the test input data ready for comparison with the test output data with a specific timing.

For example, a signature may be formed for this purpose. The signature can be an unambiguous function of the test output data and is preferably configured in such a way that the probability of the signature being correct, even though the data are false, is sufficiently low. The signature may be generated with the aid of a multiple input signature register (MISR). It may be that the signature is formed from the serial test output data or from the parallel test output data output by the serial-to-parallel conversion device S2P.

The signature generated from the test output data may be output to an external test device, where it is compared with a desired signature.

As an alternative, the signature generated may be compared in the semiconductor memory device with a desired signature stored therein. A test result signal is output to the external test device. The test result signal specifies whether or not the test requirements were met.

The desired signature may be generated experimentally or by simulation. If the desired signature is generated experimentally, a known semiconductor memory device which meets the requirements is used for generating the desired signature (so-called “known good device”). For this purpose, it is possible for example to provide relaxed time conditions or time conditions for which error-free operation can essentially be ensured, in order to enable entirely satisfactory operation of the semiconductor memory device.

If the desired signature is to be generated with the aid of a simulation, this may be effected computationally.

Instead of a signature, a redundancy may be provided in the test input data. This redundant information can then be used for generating a data test result.

For example, in the case of an 8-bit test word, i.e., a test word having a length of 8 bits, the eighth bit may represent the checksum of the other seven bits. Consequently, by checksum formation of the test output data and comparison with the respective eighth bit, it is possible to determine whether or not an error occurred during test operation.

Furthermore, a multiplicity of signature generating devices may be provided on or in the semiconductor memory device. For example, the semiconductor memory device may be designed in such a way that if the test output data are output at different locations of the semiconductor memory device, the respective locally adjacent test output data are used for calculating a signature.

As an alternative to the methods described above, it is possible to use further suitable signature or redundancy methods.

In FIGS. 1 and 2, provisions are made for a so-called “loop back” configuration for testing, in which test signals are passed via output drivers, at least one data pad and input drivers to the semiconductor memory device and are stored and/or evaluated in the semiconductor memory device.

Furthermore, provision is made in particular of a loop-back method for measuring the interface timing of semiconductor memory devices using the normal mode memory.

While the foregoing is directed to embodiments of the present invention, other and further embodiments of the invention may be devised without departing from the basic scope thereof, and the scope thereof is determined by the claims that follow.

What is claimed is:

1. A method for testing a semiconductor memory device which can be operated in a normal operating mode and a test mode, the method comprising:
selecting the test mode of operation;
communicating test input data to the semiconductor memory device;
storing the test input data in a memory area of the semiconductor memory device, wherein the memory area is configured to store the test input data in the test mode and store other data in the normal operating mode; and
outputting the stored test input data from the memory area to obtain test output data.

2. The method of claim 1, wherein the stored test input data is output from the memory area at least partially in parallel, and further comprising:
converting the test input data output in parallel from the memory area into serial data.

3. The method of claim 1, further comprising:
comparing the test output data with the output stored test input data in a comparison device.

4. The method of claim 3, further comprising:
registering an error in an error register for generating a comparison test result.

5. The method of claim 2, further comprising:
at least partially converting the test output data from serial data into parallel data to be input into the second memory area;
comparing the converted test output data with the stored test input data in a comparison device.

6. The method of claim 1, wherein an order of outputting the test input data stored in the memory area is altered to generate different test patterns.

7. A memory device which can be operated in a normal operating mode and a test mode, comprising:
a memory area configured to store test input data in the test mode and store other data in the normal operating mode; and
circuitry configured to:
place the memory device in the test mode of operation;
receive the test input data;
store the test input data in the memory area; and
output the stored test input data from the memory area to obtain test output data.

8. The memory device of claim 7, further comprising:
a second memory area configured to store the test output data in the test mode and store other data in the normal operating mode; and
wherein the circuitry is further configured to store the test output data in the second memory area.

9. The memory device of claim 8, wherein the test output data comprises serial test output data, and further comprising:
a serial to parallel converter configured to at least partially convert the serial test output data into parallel data to be input into the second memory area.

10. The memory device of claim 8, further comprising a comparison device configured to compare the stored test output data with the stored test input data.

11. The memory device of claim 10, further comprising an error register configured to register an error if the comparison device indicates that the stored test output data does not match the stored test input data.

12. The memory device of claim 8, further comprising a signature register configured to create a signature from the test output data.

13. The memory device of claim 7, further comprising:
a second memory area;
an output driver for outputting data from the memory area;
an input driver for inputting data into the second memory area;
a data pad; and
test circuitry configured to transmit the test input data via the output driver and the data pad to the input driver and the second memory area, wherein the output stored test input data is simultaneously output from and input to the semiconductor memory device.

14. The memory device of claim 13, wherein the output driver and the input driver are connected to the data pad.

15. The memory device of claim 13, further comprising:
a first contact connected to the output driver;
a second contact connected to the input driver; and
connection circuitry configured to create a connection between the first and second contact in the test mode, wherein the output stored test input data is conducted from the first contact to the second contact via the connection to the second memory area.

16. A memory device which can be operated in a normal operating mode and a test mode, comprising:
means for storing configured to store test input data in the test mode and store other data in the normal operating mode; and
means for controlling configured to:
place the memory device in the test mode of operation;
receive the test input data;
store the test input data in the means for storing; and
output the stored test input data from the means for storing to obtain test output data.

17. The memory device of claim 16, further comprising:
a second means for storing configured to store the test output data in the test mode and store other data in the normal operating mode; and
wherein the means for controlling is further configured to store the test output data in the second means for storing.

18. The memory device of claim 17, wherein the test output data comprises serial data, and further comprising:
means for converting configured to at least partially convert the serial test output data into parallel data to be input into the second means for storing.

19. The memory device of claim 18, further comprising:
means for comparing configured to compare the stored test output data with the stored test input data.

20. The memory device of claim 19, further comprising:
means for registering configured to register an error if the means for comparing indicates that the stored test output data does not match the stored test input data.

21. The memory device of claim 19, further comprising:
means for generating a signature configured to create a signature from the test output data.

22. A method for testing a semiconductor memory device which can be operated in a normal operating mode and a test mode, the method comprising:
selecting the test mode of operation;
communicating test input data to the semiconductor memory device;
storing the test input data in a memory area of the semiconductor memory device, wherein the memory area is configured to store the test input data in the test mode and store other data in the normal operating mode;
outputting the stored test input data from the memory area to obtain test output data; and
determining if the test output data is correctly obtained from the output stored test input data.

23. The method of claim 22, wherein determining if the test output data is correctly obtained from the output stored test input data comprises:
creating a data test result from the test output data.

24. The method of claim 23, wherein creating a data test result comprises:
creating a signature from the test output data.

25. The memory device of claim 24, wherein the test output data is partially combined in groups for creating the signature.

26. The memory device of claim 24, wherein determining if the test output data is correctly obtained from the output stored test input data comprises:
comparing the created signature with a desired signature.

27. The method of claim 26, wherein the comparison is performed in an external test device.

28. The method of claim 22, wherein the test output data contains redundant information, and wherein the data test result is created utilizing the redundant information of the test output data.

29. The method of claim 28, wherein the redundant information includes one or more parity bits, each parity bit containing information about a predetermined number of test input data bits provided in the test input data, and wherein the one or more parity bits are used to determine whether the test output data is correctly obtained from the output stored test input data.
